(19) United States
(12) Patent Application Publication
(10) Pub. No.: US 2007/0253214 A1
(43) Pub. Date: Nov. 1, 2007

(54) SYSTEMS AND METHODS FOR PROVIDING LIGHTING ARTICLES

(76) Inventor: Mary Beth Kaiser, Seattle, WA (US)

Correspondence Address: CLOUTIER & ENGLE, PLLC;ATTN: PRIYA SINHA CLOUTIER, 320 DAYTON STREET, SUITE 260, EDMONDS, WA, 98020, US

(21) Appl. No.: 11/468,401

(22) Filed: Aug. 30, 2006

Related U.S. Application Data
(60) Provisional application No. 60/745,747, filed on Apr. 27, 2006.

(51) Int. Cl. H01L 33/00

(52) U.S. Cl. 362/555

(57) ABSTRACT

This invention relates generally to lighting devices, and more specifically, to systems and methods for providing lighting articles. In one embodiment, the invention includes a lighting device, the lighting device including an article of manufacture; and a light source, the light source being a light emitting diode (LED); wherein the light source is embedded within the article of manufacture and configured to project light through the article of manufacture. In one particular embodiment, the article of manufacture is a flower branch defining a length, the flower branch presenting a plurality of flowers disposed along the length, the plurality of flowers being constructed from any of silk, fabric, and plastic. In yet another particular embodiment, the LED is embedded within at least one of the plurality of flowers. In a further embodiment, the LED is coupled to a wire for carrying current, the wire being embedded within the flower branch.

### PRIORITY CLAIM

This application claims priority to U.S. Provisional Application 60/745,747 filed Apr. 27, 2006. The foregoing application is hereby incorporated by reference in its entirety as if fully set forth herein.

### FIELD OF THE INVENTION

This invention relates generally to lighting devices, and more specifically, to systems and methods for providing lighting articles.

### BACKGROUND OF THE INVENTION

Lighting devices have existed since 70,000 BC, where hollow rocks, shells or other natural concave objects were filled with a moss or other wicking material which was then soaked with animal fat and subsequently ignited. These crude natural lighting devices later became more ornamental and were often hand crafted from stone or clay such as the terra cotta lamps created by the Greeks in the 7th century BC. These devices, however, were not much more than ornamental torches.

Lighting design was greatly revolutionized in the 18th century, where both light intensity and rate of fuel burning became more controlled. Fuel was typically enclosed in a container and an adjustable tube or wick was used to control the intensity of the light and the rate of fuel consumption. This method became more refined in the late 1700's when wicks were introduced, which were enclosed in a hollow glass chimney.

Commercial gas lighting was in mainstream application by the 1800's and by the 1900's most cities in the United States and Europe had streets that were lit by gas lights. During this same period, however, electric lighting was at the beginning of its development, the most famous embodiment being the electric incandescent light, which was made commercially viable by Thomas Edison in 1879. Electric lighting quickly became the dominant type of lighting device and the variety of embodiments of electric lighting devices blossomed. For example, incandescent bulbs began to appear as fixtures on walls, in table lamps, floor lamps, and lamps that were hung or integrated into ceilings. Additionally, outdoor lighting was used to illuminate areas such as pathways, pools, exteriors of buildings and streets. Not only were these lighting devices and fixtures functional, they were commonly ornamental and ascetically pleasing.

Although incandescent lighting provides a consistent and reliable form of lighting for both indoor and outdoor illumination needs and can be embodied in a variety of ways, such as chandeliers, desk lights, dome lights, wall lights, and pole lights, this form of lighting is nonetheless limited. First, the heat generated by the incandescent light bulb limits both the form and material that these lighting devices can be made from. For example, lighting fixtures commonly must be made from glass or metal because the heat generated from the incandescent light bulb would melt or potentially ignite materials such as plastic, silk, fabric, paper, or wood. Indeed, even when glass or metal is used, it must be located some distance from the incandescent bulb to avoid unsafe conditions. Thus, the heat produced by the incandescent light bulb precludes proximate use of plastic, silk, fabric, paper, wood, or other materials.

Additionally, because incandescent lights burn out and need to be replaced, potential embodiments of incandescent lighting devices are further limited. To facilitate removal and replacement of spent incandescent bulbs, the lighting device needs to be open or there needs to be some means for opening the lighting device to remove and replace spent bulbs. Therefore it is impossible for incandescent light bulbs to be integrated directly into materials or articles of manufacture. Moreover, even if incandescent light bulbs could be integrated into articles of manufacture, these articles of manufacture would additionally suffer because incandescent bulbs are bulky in size.

Next, because of the limitations on the materials, limited safe sizes of fixtures and inability to integrate with articles of manufacture, incandescent light devices are commonly large and obtrusive house wares or fixtures that serve the sole purpose of illumination. Not only do these lighting devices take up a large amount of space, they also lack versatility and are difficult to conceal. As a result, both indoor and outdoor areas that require lighting can appear cluttered with lighting devices and such devices are obtrusive even when not being used for illumination. This is important because people are beginning to live in more space constrained areas and smaller homes, such as condominiums, where there is not much space. Many such homes include only a few hundred square feet of living space, despite costing hundreds of thousands of dollars. The small amount of living space means that every piece of furniture or lighting device directly reduces comfort and movability within the home.

Accordingly, what is needed are lighting devices that function as both a source of illumination and one or more other function, without suffering from material, lifespan, and size limitations. What is needed, therefore, are systems and methods for providing lighting articles.

### SUMMARY OF THE INVENTION

This invention relates generally to lighting devices, and more specifically, to systems and methods for providing lighting articles. In one embodiment, the invention includes a lighting device, the lighting device including an article of manufacture and a light source, which is a light emitting diode (LED) and where the light source is embedded within the article of manufacture and configured to project light through the article of manufacture. In one particular embodiment, the article of manufacture is a flower branch defining a length, the flower branch presenting a plurality of flowers disposed along the length, the plurality of flowers being constructed from any of silk, fabric, and plastic. In yet another particular embodiment, the LED is embedded within at least one of the plurality of flowers. In a further embodiment, the LED is coupled to a wire for carrying current, the wire being embedded within the flower branch.

### BRIEF DESCRIPTION OF THE DRAWINGS

FIG. 1 is a side elevational view of a lighting device integrated into bamboo, in accordance with an embodiment of the invention;

FIG. 2 is a cross section view of a lighting device integrated into bamboo, in accordance with an embodiment of the invention;

FIG. 3 is a side elevational view of a lighting device integrated into a pussy willow, in accordance with an embodiment of the present invention;

FIG. 4 is a cross section view of a lighting device integrated into a pussy willow, in accordance with an embodiment of the present invention;

FIG. 5 is a side elevational view of a lighting device integrated into a flower, in accordance with an embodiment of the present invention;

FIG. 6 is a cross section view of a lighting device integrated into a flower, in accordance with an embodiment of the present invention;

FIG. 7 is a side elevational view of a lighting device integrated into a flower, in accordance with an embodiment of the present invention;

FIG. 8 is a top perspective view of a lighting device integrated into a flower, in accordance with an embodiment of the present invention;

FIG. 9 is a cross section view of a lighting device integrated into a flower, in accordance with an embodiment of the present invention;

FIG. 10 is a side elevational view of a lighting device integrated into a flower, in accordance with an embodiment of the present invention;

FIG. 11 is a top perspective view of a lighting device integrated into a flower, in accordance with an embodiment of the present invention;

FIG. 12 is a cross section view of a lighting device integrated into a flower, in accordance with an embodiment of the present invention;

FIG. 13 is a side elevational view of a lighting device integrated into a flower, in accordance with an embodiment of the present invention;

FIG. 14 is a top perspective view of a lighting device integrated into a flower, in accordance with an embodiment of the present invention;

FIG. 15 is a cross section view of a lighting device integrated into a flower, in accordance with an embodiment of the present invention; and

FIG. 16 is a side elevational view of a lighting device integrated into bamboo, in accordance with an embodiment of the present invention.

### DETAILED DESCRIPTION

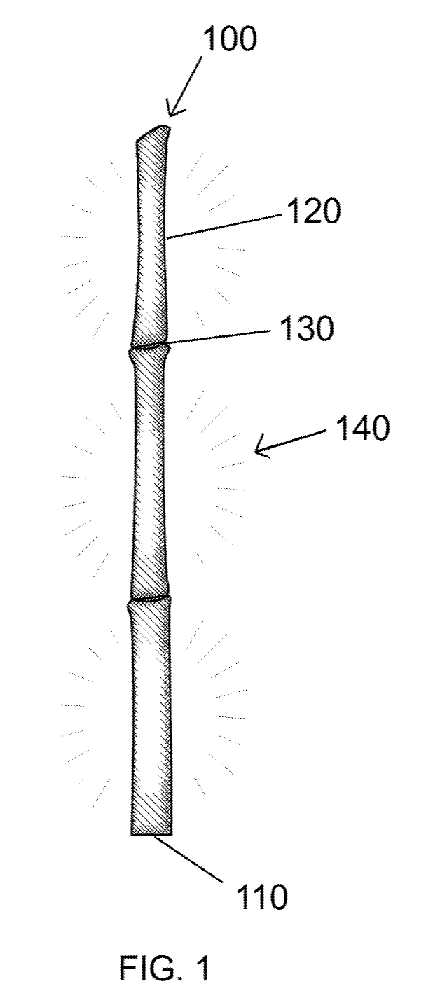

This invention relates generally to lighting devices, and more specifically, to systems and methods for providing lighting articles. Specific details of certain embodiments of the invention are set forth in the following description and in FIGS. 1-16 to provide a thorough understanding of such embodiments. The present invention may have additional embodiments, or may be practiced without one or more of the details described for any particular described embodiment.

FIG. 1 is a side elevational view of a lighting device integrated into bamboo, in accordance with an embodiment of the invention. In one embodiment, lighting stick 100 comprises a light cover 110 in the shape of bamboo. The light cover 110 further comprises one or more bamboo segment 120, and where there are two or more bamboo segments 120, the bamboo segments 120 are joined at a segment junction 130.

Within the light cover 110 is a light source (not shown), which emits light 140. In one embodiment, the lighting cover 110 comprises any transparent, semi-transparent or non-opaque material including, but not limited to, plastic, silk, fabric, rubber, glass, bamboo, ceramic, or any other natural or non-natural material that allows light 140 to emanate or pass through the light cover 110 from the light source (not shown). In a further embodiment, the lighting cover may include one or more transparent, semi-transparent or non-opaque material and may further include an opaque material. Furthermore, lighting cover 110 may comprise one or more color or texture, and may vary in opacity and transparency to create variance in the intensity and/or quality of the transmittance of light 140.

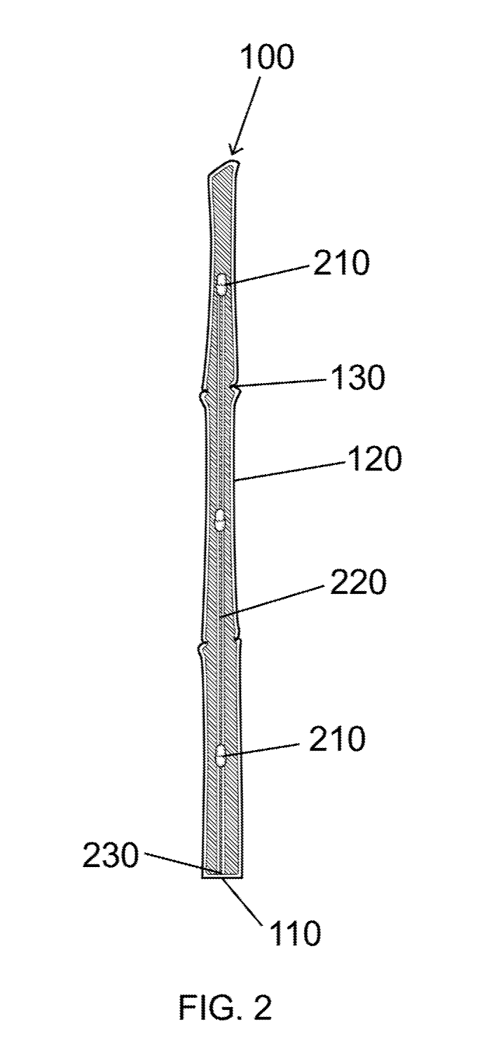

FIG. 2 is a cross section view of a lighting device integrated into bamboo, in accordance with an embodiment of the invention. In one embodiment, the lighting stick 100 includes a lighting cover 110, which further comprises one or more bamboo segment 120. In certain embodiments where there are two or more bamboo segments 120, these segments 120 are joined at a segment junction 130. Additionally, within the lighting cover there is one or more light source 210 and the one or more light source 210 is connected by a wire 220. Moreover, one segment of the wire 220 is a terminal end of the wire 230. In one embodiment, the terminal end of the wire is connected to another wire (not shown) or a power source (not shown), such as a common wall receptacle, battery, solar cell, or other method of providing energy, either known or unknown. In a still further embodiment of the invention, the power source provides a source of one or more electrons that travel through the wire 220, where the one or more electrons provide energy to the one or more light source 210 whereby light 140 (FIG. 1) is generated by the light source 210.

In certain embodiments, the light source 210 may be any of incandescent, fluorescent, gas, liquid crystal, but preferably light emitting diodes or LED's. In one embodiment light source 210 may emit one or more wavelength of light, including light in the visible range which be can viewed as colors such as red, orange, yellow, green, blue, indigo, and violent, or light in the non-visible range such as x-rays or microwaves. In another embodiment, the one or more light source 210 may emit light of a wavelength that is different from the light emitted from one or more other light source 210. In yet a further embodiment, the one or more light source 210 may emit light of a combination of wavelengths, such as white light.

In a further embodiment the wire 220 may comprise one or more means of conveying energy to and from the power source (not shown), such means including but not limited to, alternating current and direct current. In one embodiment the wire 220 may be absent; however, in further embodiments, the wire may be comprised of one or more materials such as plastic, silk, fabric, metal, glass, or ceramics.

In a yet further embodiment of the invention, the wire 220 connecting the one or more light source to a power source may further comprise other elements, such as transistors, resistors and switches, which may be present in any position on the wire 220 and therefore in any position in, on, or within the lighting cover 110.

FIG. 2 depicts a lighting stick 100 comprising three bamboo segments 120, where there is a light source 210 located approximated half-way between a first and second end of each of the bamboo segments 120. In other embodiments, the invention may include one or more bamboo segment 120 and one or more light source 210, where the one or more light source 210 may be located at any position between the first and second end of the bamboo segment 120. In a still further embodiment, there may be no light source 210 in the one or more bamboo segment 120. In a yet further embodiment, one or more light source 210 may be located at the segment junction 130.

In one embodiment, any of the wire 220 or the one or more light source 210 may be directly integrated or incased in the light cover 110, where the light cover 110 is in direct contact with any of the wire 220 or the one or more light source 210. In a yet further embodiment, the light cover 110 is hollow and is not in direct contact with any of the wire 220 or the one or more light source 210. In a still further embodiment, the wire 220 or the one or more light source 210 may be connected to the light cover 110 by a fastening means such as a clip, a strap, a harness, tape, glue, or wax.

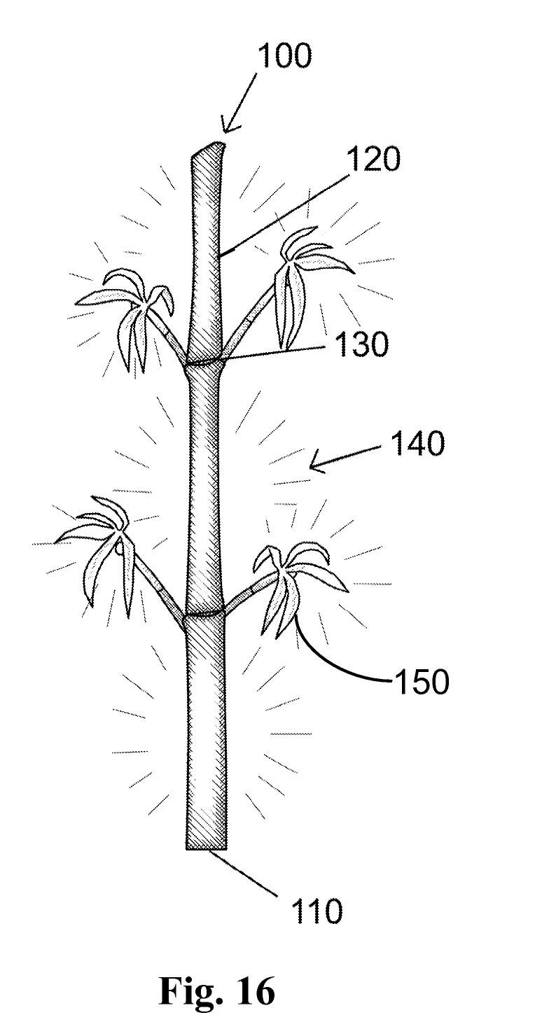

FIG. 16 is a side elevational view of a lighting device integrated into bamboo, in accordance with an embodiment of the invention. In one embodiment, lighting stick 100 comprises a light cover 110 in the shape of bamboo. The light cover 110 further comprises one or more bamboo segment 120, and where there are two or more bamboo segments 120, the bamboo segments 120 are joined at a segment junction 130. Additionally, the light cover 110 further comprises one or more bamboo bud 150. In one embodiment one or more bamboo bud 150 is located at a segment junction 130. In a further embodiment, one more bamboo bud 150 can be located at any position along or on one or more bamboo segment 120. In an alternative embodiment, the one or more light source 210 is positioned within or proximate to the one or more bamboo bud 150.

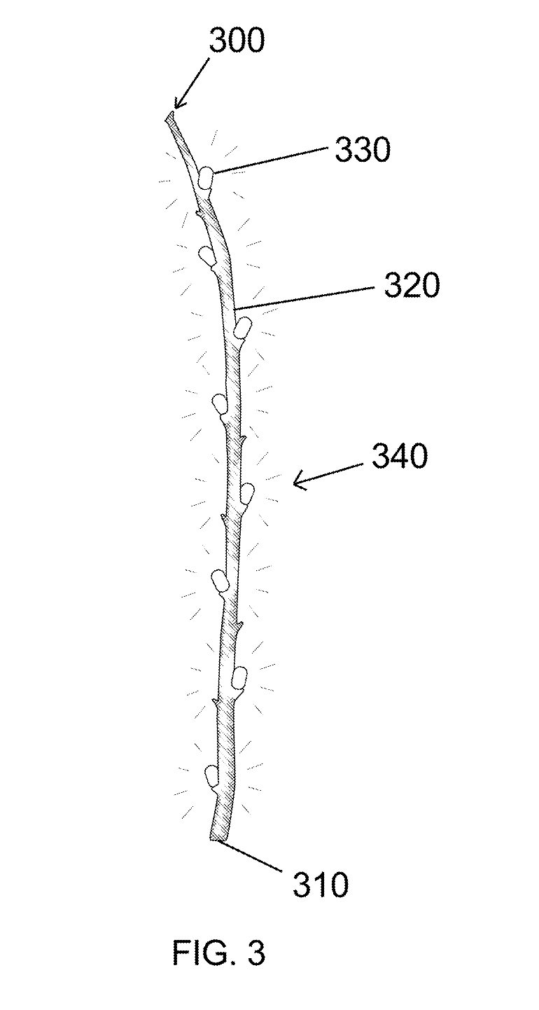

FIG. 3 is a side view of a lighting device integrated into a pussy willow, in accordance with an embodiment of the invention. In one embodiment, lighting stick 300 includes a light cover 310, which further includes a stem 320 and one or more bud 330. Within the light cover is a light source (not shown). In one embodiment, the lighting cover 310 comprises any transparent, semi-transparent or non-opaque material including, but not limited to, plastic, silk, fabric, rubber, glass, ceramic, or any other natural or non-natural material that allows light 340 to emanate or pass through the light cover 310 from the light source (not shown). In a further embodiment, the lighting cover may include one or more transparent, semi-transparent or non-opaque material and may further comprise an opaque material. Furthermore, lighting cover 310 may comprise one or more color, texture, and may vary in opacity and transparency to create variance in the transmittance of light 340.

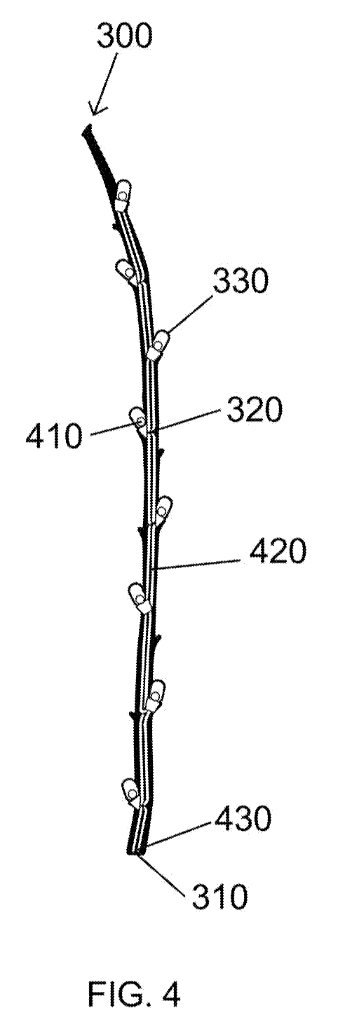

FIG. 4 is a cross section view of a lighting device integrated into a pussy willow, in accordance with an embodiment of the invention. In one embodiment, lighting stick 300 includes a lighting cover 310, which further includes a stem 320 and one or more bud 330. Additionally, within the lighting cover there is one or more light source 410 and the one or more light source 410 is connected by a wire 420. In one particular embodiment, the one or more light source 410 is an LED. Moreover, one segment of the wire 420 is a terminal end of the wire 430. In one embodiment, the terminal end of the wire is connected to another wire (not shown) or a power source (not shown) such as a common wall receptacle, battery, solar cell, or other means of providing energy, either known or unknown. In a still further embodiment of the invention, the power source (not shown) provides a source of one or more electrons that travel through the wire 420, where the one or more electrons provide energy to the one or more light source 410 whereby light is generated by the light source 410.

In one embodiment of the invention, the one or more light source 410 is located within the one or more bud 330; however, in a further embodiment one or more light source may be located in the stem 320 or one or more light source may be located in both the stem 320 and within the one or more bud 330. In further embodiments the light cover 310 may vary by material, texture, color, number of bud, transparency, and design.

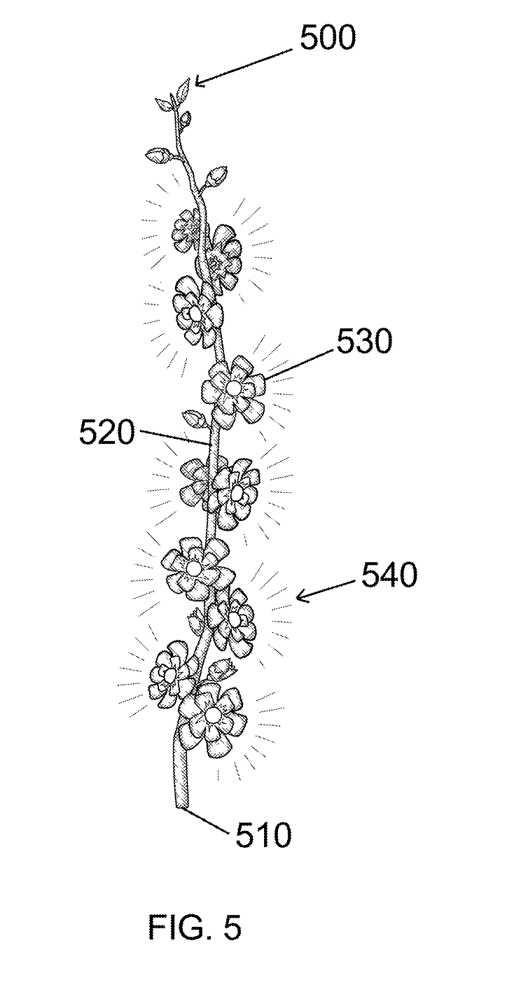

FIG. 5 is a side view of a lighting device integrated into a flower, in accordance with an embodiment of the invention. In one embodiment, lighting stick 500 includes a light cover 510, which further includes a stem 520 and one or more flower 530. The lighting stick 500 includes a light source (not shown) within the light cover 510. In one embodiment, the lighting cover 510 comprises any transparent, semi-transparent or non-opaque material including, but not limited to, plastic, silk, fabric, rubber, glass, ceramic, or any other natural or non-natural material that allows light 540 to emanate or pass through the light cover 510. In a further embodiment, the lighting cover may include one or more transparent, semi-transparent or non-opaque material and may further comprise an opaque material. Furthermore, lighting cover 510 may comprise one or more color, texture, and may vary in opacity and transparency to create variance in the transmittance of light 540.

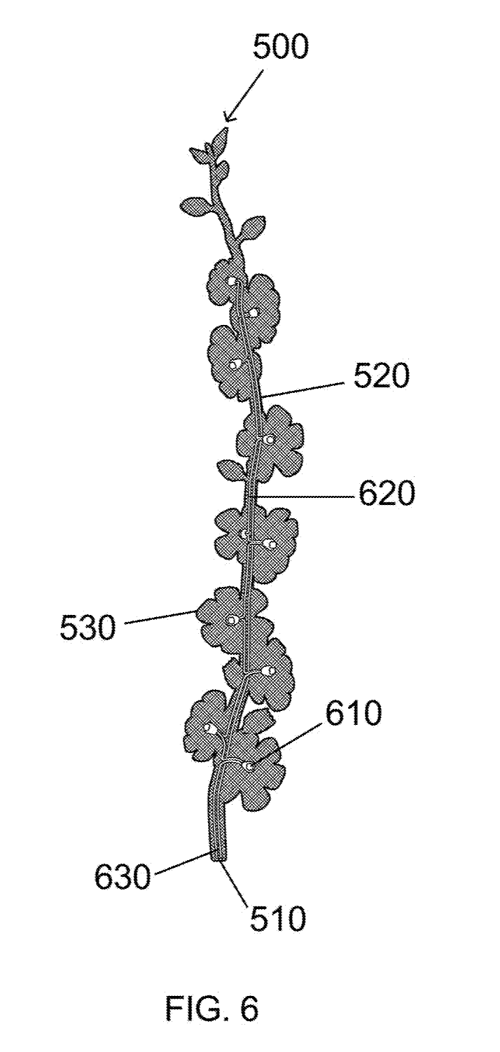

FIG. 6 is a cross section view of a lighting device integrated into a flower, in accordance with an embodiment of the invention. In one embodiment, lighting stick 500 includes a lighting cover 510, which further comprises a stem 520 and one or more flower 530. Additionally, within the lighting cover there is one or more light source 610 and the one or more light source is connected by a wire 620. Moreover, a segment of the wire 620 is a terminal end of the wire 630. In one embodiment, the terminal end of the wire is connected to another wire (not shown) or a power source (not shown) such as a common wall receptacle, battery, solar cell, or other means of providing energy, either known or unknown. In a still further embodiment of the invention, the power source (not shown) provides a source of one or more electrons that travel through the wire 620, where the one or more electrons provide energy to the one or more light source 610 whereby light is generated by the light source 610.

In one embodiment of the invention, the one or more light source 610 is located within the flower 530; however, in a further embodiment one or more light source 610 may be located in the stem 520 or the one or more light source may be located in both the stem 520 and within the one or more flower 530. As described herein, further embodiments the light cover 510 may vary by material, texture, color, number of flower, transparency, and design.

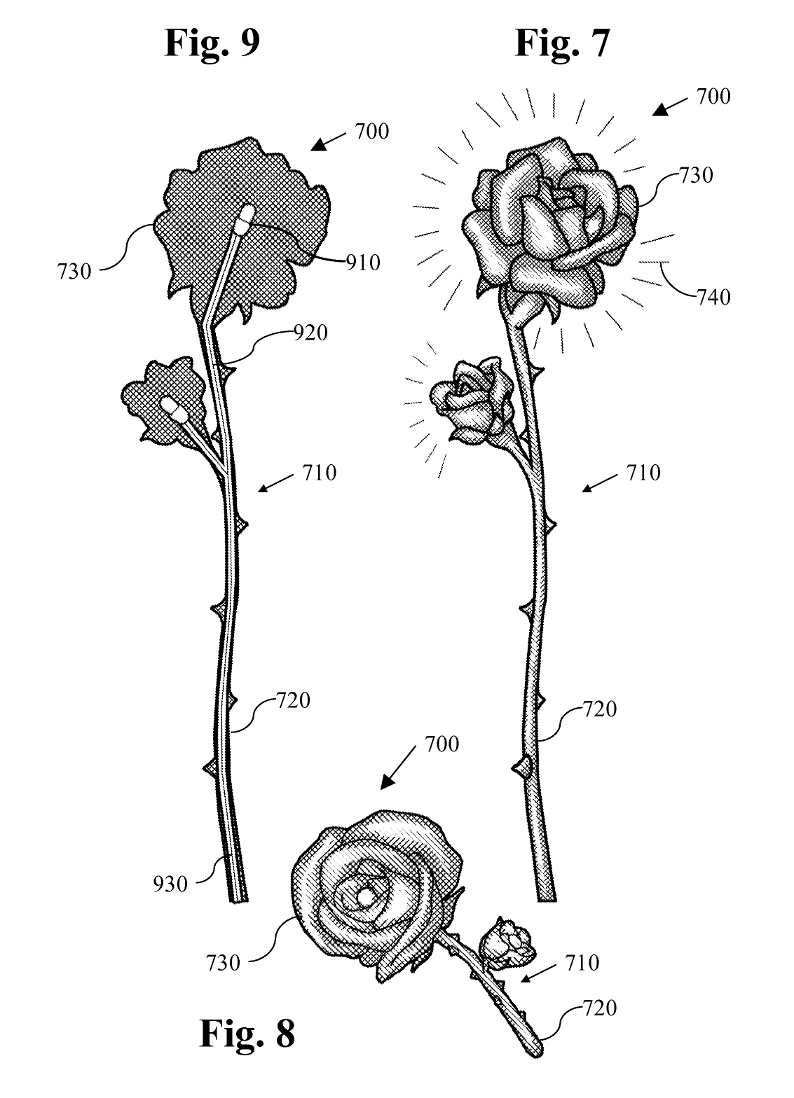

FIG. 7 is a side elevational view of a lighting device integrated into a flower, in accordance with an embodiment of the present invention. In one embodiment, lighting stick 700 includes a light cover 710, which further includes a stem 720 and one or more flower 730. The lighting stick 700 includes a light source (not shown) within the light cover 710. In one embodiment, the lighting cover 710 comprises any transparent, semi-transparent or non-opaque material including, but not limited to, plastic, silk, fabric, rubber, glass, ceramic, or any other natural or non-natural material that allows light 740 to emanate or pass through the light cover 710. In a further embodiment, the lighting cover may include one or more transparent, semi-transparent or non-opaque material and may further comprise an opaque material. Furthermore, lighting cover 710 may comprise one or more color, texture, and may vary in opacity and transparency to create variance in the transmittance of light 740.

FIG. 8 is a top perspective view of a lighting device integrated into a flower, in accordance with an embodiment of the present invention. FIG. 8 illustrates various embodiments discussed in reference to FIG. 7.

FIG. 9 is a cross section view of a lighting device integrated into a flower, in accordance with an embodiment of the present invention. In one embodiment, lighting stick 700 includes a lighting cover 710, which further comprises a stem 720 and one or more flower 730. Additionally, within the lighting cover there is one or more light source 910 and the one or more light source is connected by a wire 920. Moreover, a segment of the wire 920 is a terminal end of the wire 930. In one embodiment, the terminal end of the wire is connected to another wire (not shown) or a power source (not shown) such as a common wall receptacle, battery, solar cell, or other means of providing energy, either known or unknown. In a still further embodiment of the invention, the power source (not shown) provides a source of one or more electrons that travel through the wire 920, where the one or more electrons provide energy to the one or more light source 910 whereby light is generated by the light source 910.

In one embodiment of the invention, the one or more light source 910 is located within the flower 730; however, in a further embodiment one or more light source 910 may be located in the stem 720 or the one or more light source may be located in both the stem 720 and within the one or more flower 730. As described herein, further embodiments the light cover 710 may vary by material, texture, color, number of flower, transparency, and design.

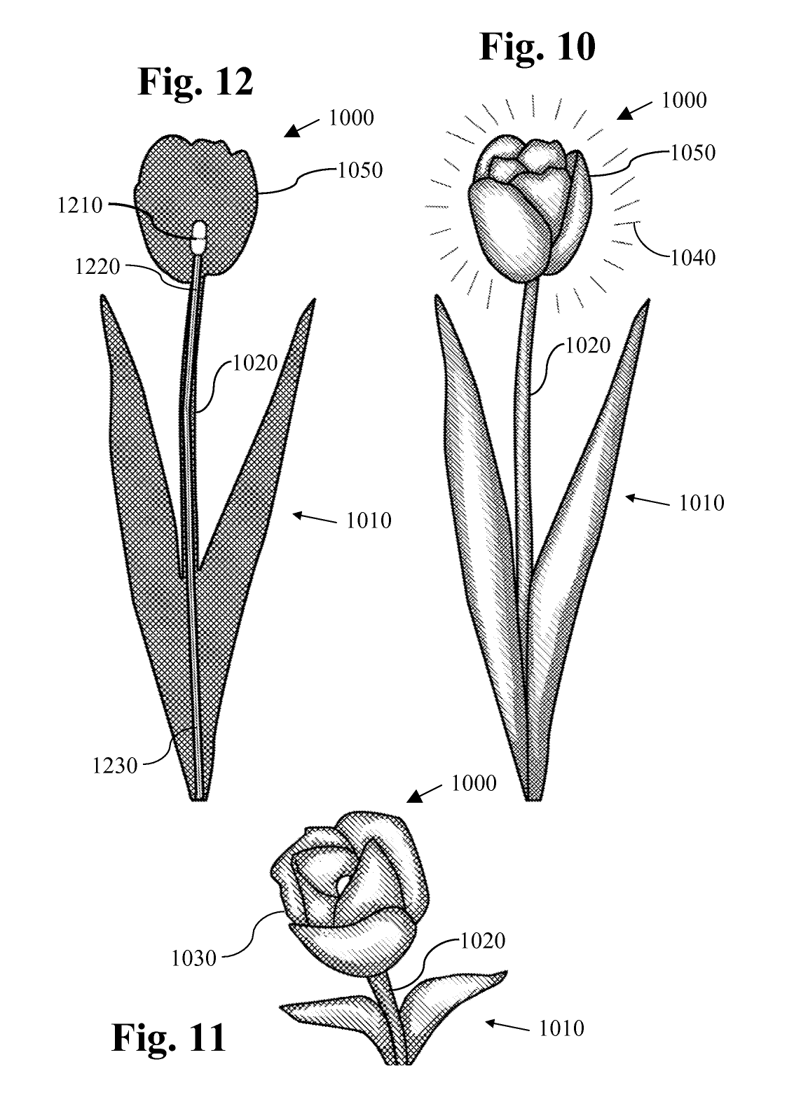

FIG. 10 is a side elevational view of a lighting device integrated into a flower, in accordance with an embodiment of the present invention. In one embodiment, lighting stick 1000 includes a light cover 1010, which further includes a stem 1020 and one or more flower 1030. The lighting stick 1000 includes a light source (not shown) within the light cover 1010. In one embodiment, the lighting cover 1010 comprises any transparent, semi-transparent or non-opaque material including, but not limited to, plastic, silk, fabric, rubber, glass, ceramic, or any other natural or non-natural material that allows light 1040 to emanate or pass through the light cover 1010. In a further embodiment, the lighting cover may include one or more transparent, semi-transparent or non-opaque material and may further comprise an opaque material. Furthermore, lighting cover 1010 may comprise one or more color, texture, and may vary in opacity and transparency to create variance in the transmittance of light 1040.

FIG. 11 is a top perspective view of a lighting device integrated into a flower, in accordance with an embodiment of the present invention. FIG. 11 illustrates various embodiments discussed in reference to FIG. 10.

FIG. 12 is a cross section view of a lighting device integrated into a flower, in accordance with an embodiment of the present invention. In one embodiment, lighting stick 1000 includes a lighting cover 1010, which further comprises a stem 1020 and one or more flower 1030. Additionally, within the lighting cover there is one or more light source 1210 and the one or more light source is connected by a wire 1220. Moreover, a segment of the wire 1220 is a terminal end of the wire 1230. In one embodiment, the terminal end of the wire is connected to another wire (not shown) or a power source (not shown) such as a common wall receptacle, battery, solar cell, or other means of providing energy, either known or unknown. In a still further embodiment of the invention, the power source (not shown) provides a source of one or more electrons that travel through the wire 1220, where the one or more electrons provide energy to the one or more light source 1210 whereby light is generated by the light source 1210.

In one embodiment of the invention, the one or more light source 1210 is located within the flower 1030; however, in a further embodiment one or more light source 1210 may be located in the stem 1020 or the one or more light source may be located in both the stem 1020 and within the one or more flower 1030. As described herein, further embodiments the light cover 1010 may vary by material, texture, color, number of flower, transparency, and design.

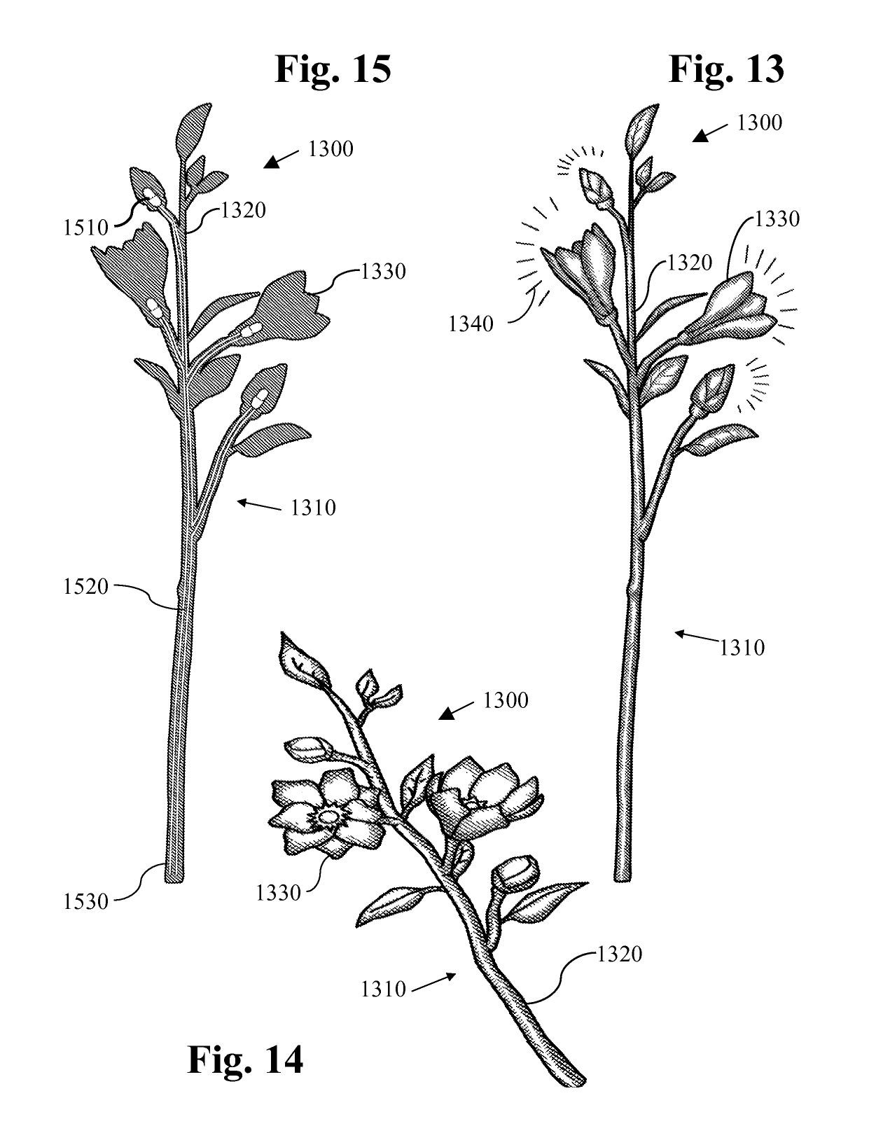

FIG. 13 is a side elevational view of a lighting device integrated into a flower, in accordance with an embodiment of the present invention. In one embodiment, lighting stick 1300 includes a light cover 1310, which further includes a stem 1320 and one or more flower 1330. The lighting stick 1300 includes a light source (not shown) within the light cover 1310. In one embodiment, the lighting cover 1310 comprises any transparent, semi-transparent or non-opaque material including, but not limited to, plastic, silk, fabric, rubber, glass, ceramic, or any other natural or non-natural material that allows light 1340 to emanate or pass through the light cover 1310. In a further embodiment, the lighting cover may include one or more transparent, semi-transparent or non-opaque material and may further comprise an opaque material. Furthermore, lighting cover 1310 may comprise one or more color, texture, and may vary in opacity and transparency to create variance in the transmittance of light 1340.

FIG. 14 is a top perspective view of a lighting device integrated into a flower, in accordance with an embodiment of the present invention. FIG. 14 illustrates various embodiments discussed in reference to FIG. 13.

FIG. 15 is a cross section view of a lighting device integrated into a flower, in accordance with an embodiment of the present invention. In one embodiment, lighting stick 1300 includes a lighting cover 1310, which further comprises a stem 1320 and one or more flower 1330. Additionally, within the lighting cover there is one or more light source 1510 and the one or more light source is connected by a wire 1520. Moreover, a segment of the wire 1520 is a terminal end of the wire 1530. In one embodiment, the terminal end of the wire is connected to another wire (not shown) or a power source (not shown) such as a common wall receptacle, battery, solar cell, or other means of providing energy, either known or unknown. In a still further embodiment of the invention, the power source (not shown) provides a source of one or more electrons that travel through the wire 1520, where the one or more electrons provide energy to the one or more light source 1510 whereby light is generated by the light source 1510.

In one embodiment of the invention, the one or more light source 1510 is located within the flower 1330; however, in a further embodiment one or more light source 1510 may be located in the stem 1320 or the one or more light source may be located in both the stem 1320 and within the one or more flower 1330. As described herein, further embodiments the light cover 1310 may vary by material, texture, color, number of flower, transparency, and design.

In a further embodiment, a light cover may be in the form of any article of manufacture or otherwise, including house-wares of both indoor and outdoor use, as well as elements of buildings or architecture. For example, in some embodiments of the present invention the light cover may comprise or resemble a picture frame, basket, vase, newspaper/magazine rack, toy box, chair, coffee table, bed, desk, bookcase, cabinet, pillar, door trim, wall, rock, step, awning, lamp shade, recipe holder, or any other article of manufacture that may be used in a home, office, factory or other area, including outdoor areas such as yards, parks, parking lots and driveways.

In one particular embodiment, the invention includes a vase, wherein the bottom of the vase includes a light source. The light source is configurable to project light through water or plants contained within the vase.

While preferred and alternate embodiments of the invention have been illustrated and described, as noted above, many changes can be made without departing from the spirit and scope of the invention. Accordingly, the scope of the invention is not limited by the disclosure of these preferred and alternate embodiments. Instead, the invention should be determined entirely by reference to the claims that follow.

What is claimed is:

1. A lighting device, the lighting device comprising
an article of manufacture; and
a light source, the light source being a light emitting diode (LED);
wherein the light source is embedded within the article of manufacture and configured to project light through the article of manufacture.

2. The lighting device of claim 1, wherein the article of manufacture is a flower branch defining a length, the flower branch presenting a plurality of flowers disposed along the length, the plurality of flowers being constructed from any of silk, fabric, and plastic.

3. The lighting device of claim 2, wherein the LED is embedded within at least one of the plurality of flowers.

4. The lighting device of claim 2, wherein the LED is coupled to a wire for carrying current, the wire being embedded within the flower branch.

5. The lighting device of claim 1, wherein the article of manufacture is a bamboo branch defining a length, the bamboo branch being constructed from any of wood and plastic.

6. The lighting device of claim 5, further comprising a plurality of LED, wherein the plurality of LED are embedded along the length of the bamboo branch.

7. The lighting device of claim 5, wherein the LED is coupled to a wire for carrying current, the wire being embedded within the bamboo branch.

8. The lighting device of claim 1, wherein the article of manufacture is a pussy willow branch defining a length, the pussy willow branch presenting a plurality of bulbs along the length, the plurality of bulbs being constructed from any of silk, fabric, and plastic.

9. The lighting device of claim 8, wherein the LED is embedded within at least one of the plurality of bulbs.

10. The lighting device of claim 8, wherein the LED is coupled to a wire for carrying current, the wire being embedded within the pussy willow branch.

11. The lighting device of claim 1, wherein the article of manufacture is a flower on a stem, the flower and the stem being constructed from any of silk, fabric, and plastic.

12. The lighting device of claim 11, wherein the LED is embedded within the flower.

13. The lighting device of claim 11, wherein the LED is coupled to a wire for carrying current, the wire being embedded within the stem.
